(19) United States
(12) Patent Application Publication
(10) Pub. No.: US 2024/0276654 A1
(43) Pub. Date: Aug. 15, 2024

(54) CONTROLLER ASSEMBLY FOR A POWER UNIT

(71) Applicant: Honda Motor Co., Ltd., Tokyo (JP)

(72) Inventors: Christopher Todd Walker, Hillsborough, NC (US); Shivang Desai, Mebane, NC (US); Kyle E. Long, Hurdle Mills, NC (US)

(21) Appl. No.: 18/169,457

(22) Filed: Feb. 15, 2023

(51) Int. Cl. H05K 5/00; H05K 5/02

(52) U.S. Cl. CPC H05K 5/0008; H05K 5/0217

(57) ABSTRACT

A controller assembly for a power unit includes a controller and a casing for supporting the controller and adapted to be mounted to a frame of the power unit. The casing includes at least one engagement structure arranged at a first end of the casing and configured to be coupled to the frame, and a plurality of screw brackets arranged at a second end disposed opposite to the first end and configured to facilitate a coupling of the casing with the frame via a plurality of fasteners. At least one grommet is adapted to be removably engaged with the at least one engagement structure and the frame to enable the mounting of the casing to the frame.

### BACKGROUND

The disclosed subject matter relates generally to a controller assembly for a power unit. More particularly, the disclosed subject matter relates to a controller assembly for a power unit of a power equipment.

Power equipment tools, such as, lawn mowers, use electronic controllers that either mounting using or held sandwiched between two components of the power equipment. These types of mountings have problems in extreme load situations like blade impact, front impact or fatigue loading which can cause mount failure if controller is heavy weight. Controller can cause rattle due to machine vibration if not mounted fixed, which is undesirable.

### SUMMARY

In accordance with one embodiment of the present disclosure, a controller assembly for a power unit is provided. The controller assembly includes a controller and a casing for supporting the controller and adapted to be mounted to a frame of the power unit. The casing includes at least one engagement structure arranged at a first end of the casing and configured to be coupled to the frame, and a plurality of screw brackets arranged at a second end disposed opposite to the first end and configured to facilitate a coupling of the casing with the frame via a plurality of fasteners. The controller assembly also includes at least one grommet adapted to be removably engaged with the at least one engagement structure and the frame to enable the mounting of the casing to the frame.

In accordance with another embodiment of the present disclosure, a power unit for a power equipment is provided. The power unit includes a frame having at least one bracket and a controller assembly removably mounted to the frame. The controller assembly includes a controller, and a casing for supporting the controller and mounted to the frame. The casing includes at least one engagement structure arranged at a first end of the casing and configured to be coupled to the at least one bracket, and a plurality of screw brackets arranged at a second end disposed opposite to the first end and configured to facilitate a coupling of the casing with the frame via a plurality of fasteners. The controller assembly further includes at least one grommet removably coupling the at least one engagement structure of the casing with the at least bracket of the frame.

In accordance with yet a further embodiment of the present disclosure, a controller assembly for a power unit is provided. the controller assembly includes a controller and a casing for supporting the controller and adapted to be mounted to a frame of the power unit. The casing includes at least one engagement structure arranged at a first end of the casing and configured to be coupled to the frame. The at least one engagement structure includes a protrusion. The casing also includes a plurality of screw brackets arranged at a second end disposed opposite to the first end and configured to facilitate a coupling of the casing with the frame via a plurality of fasteners. The controller assembly further includes at least one grommet made of rubber and configured to couple the casing and the frame. The at least one grommet defines a cavity to receive the protrusion of the at least one engagement structure to couple the casing with the at least one grommet, and a receptacle to receive the at least one bracket of the frame to enable a coupling of the at least one grommet with the frame.

### BRIEF DESCRIPTION OF THE DRAWINGS

Certain embodiments of the present disclosure will be better understood from the following description taken in conjunction with the accompanying drawings in which:

FIG. 1 is a front perspective view of a portion of a power equipment depicting a power unit having a motor controller assembly as a controller assembly mounted to a frame of the power unit, in accordance with at least one embodiment of the present disclosure;

FIG. 2 is an exploded view an electronic transmission controller assembly as the controller assembly, in accordance with at least one embodiment of the present disclosure;

FIG. 3 is a front perspective of the frame of the power unit depicting a bracket, in accordance with at least one embodiment of the present disclosure;

FIG. 4 is a top perspective view of the controller assembly of FIG. 1, in accordance with at least one embodiment of the present disclosure; and

FIG. 5 is an exploded view of the controller assembly of FIG. 4 depicting a bottom perspective view of a grommet of the controller assembly, in accordance with at least one embodiment of the present disclosure.

### DETAILED DESCRIPTION OF EXEMPLARY EMBODIMENTS

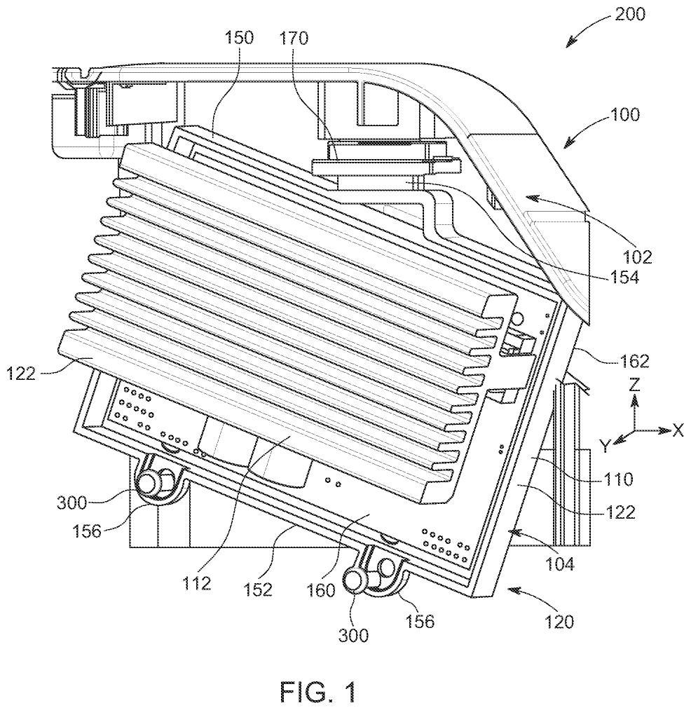

A few inventive aspects of the disclosed embodiments are explained in detail below with reference to the various figures. Exemplary embodiments are described to illustrate the disclosed subject matter, not to limit its scope, which is defined by the claims. Those of ordinary skill in the art will recognize a number of equivalent variations of the various features provided in the description that follows. Embodiments are hereinafter described in detail in connection with the views and examples of FIGS. 1-5, wherein like numbers indicate the same or corresponding elements throughout the views.

Referring to FIG. 1, a power unit 100 for a power equipment 200 is shown. In an embodiment, the power equipment 200 may include a lawn mower, a generator, a pump, a snow blower, a tiller, a trimmer, or any other similar equipment configured to be electrically operated. As shown, the power unit 100 includes a frame 102 configured to support various electrical and electronic components of the power unit 100, and a controller assembly 104 mounted to the frame 102. The controller assembly 104 includes a casing 110 and one or more controllers 112 configured to control one or more function of the power unit 100 and/or the power equipment 200. In an embodiment, the controller assembly 104 may be a motor controller assembly 120 having the controller 112 as a motor controller 122 that is configured to control an operation and functioning of an electrical motor (not shown) of the power equipment 200.

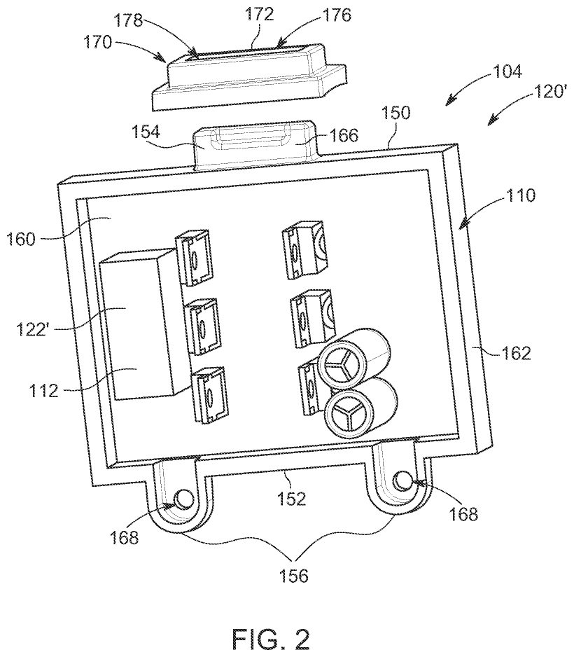

In some embodiments, as shown in FIG. 2, the controller assembly 104 may be an electronic transmission controller assembly 120′ having an electronic transmission controller 122′ to control the electronic transmission of the power equipment 200. Although the controller assembly 104 is contemplated as the motor controller assembly 120 or the electronic transmission controller assembly 120′, it may be envisioned that the controller assembly 104 may any other type of controller assembly that is suitable for controlling one or more functions or systems of the power equipment 200.

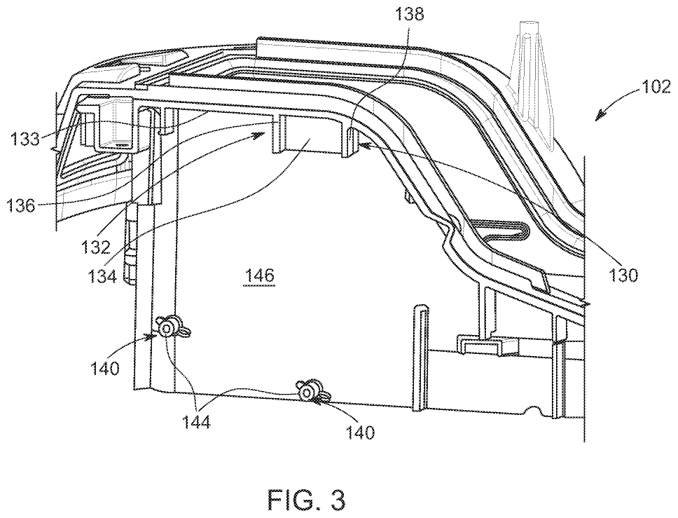

Referring to FIGS. 1 and 3, to facilitate the mounting of the controller assembly 104 to the frame 102 of the power unit 100, and support the controller assembly 104, the frame 102 may include at least one bracket 130 (best shown in FIG. 3) adapted to be coupled to the casing 110 of the controller assembly 104. Although a single bracket 130 is shown and contemplated for a single controller 112, it may be appreciated that the frame 102 may include a plurality of brackets 130 to enable the mounting of a single controller 130 or a plurality of controllers. As shown, in an embodiment, the bracket 130 includes a protrusion 132 extending downwardly from a first surface 133 of the frame 102. In an embodiment, the protrusion 132 (i.e., the bracket 130) includes a horizontally oriented I shape having a column 134 and two flanges 136, 138 arranged at two ends of the column 134. The two flanges 136, 128 extend substantially perpendicularly to the column 134, and the column 134 is arranged substantially centrally of each of the two flanges 136, 138. Although the bracket 130 is contemplated to include a horizontally oriented I shaped protrusion, it may be appreciated that the bracket 130 may include any other suitable shape that facilitates a coupling/engagement/mounting of the controller assembly 104 (i.e., casing 110) to the frame 102 of the power unit 100.

Additionally, as shown in FIG. 3, the frame 102 includes a plurality of screw mounts, for example, two screw mounts 140 to facilitate the engagement and retention of the controller assembly 104 (i.e., the casing 110) with the frame 102 using a plurality of screws 300. As shown, each of the screw mounts 140 includes a boss 144 extending outwardly from a second surface 146 of the frame 102. As shown, the first surface 133 from which the bracket 130 extends is arranged/disposed substantially perpendicularly to the second surface 146 of the frame 102. The bracket 130 and the bosses 144 are arranged such that the controller assembly 104 is sandwiched between the bracket 130 and the screw mounts 140.

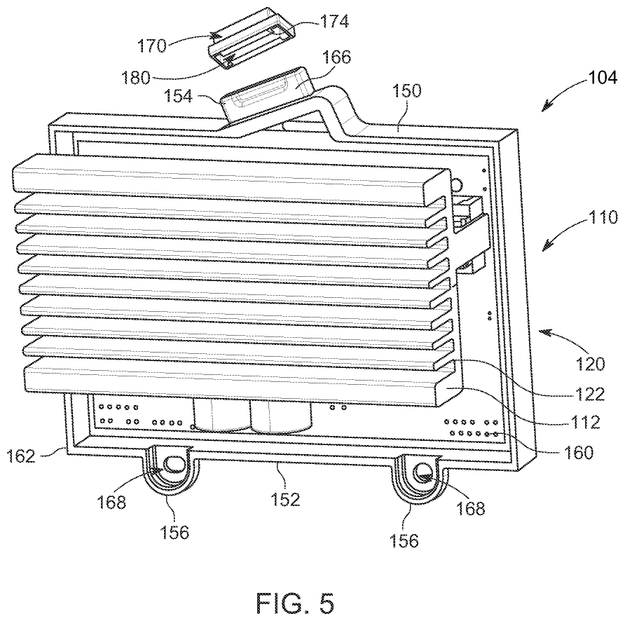

Referring to FIGS. 1-5, the exemplary casing 110 to which the controller 102 is mounted includes a first end 150 and a second end 152 arranged opposite to the first end 150, at least one engagement structure 154 (best shown in FIG. 5) arranged at the first end 150 of the casing 110 and adapted to be coupled to the bracket 130 of the frame, and a plurality of screw brackets, for example, two screw brackets 156, disposed at the second end 152 and configured to be coupled to the screw mounts 140. In an embodiment, the casing 110 may include a central plate 160 and a flange structure 162 extending along a periphery of the central plate 160 and surrounding the central plate 160. As shown, the engagement structure 154 extends outwardly of the flange structure 162 in a first direction, while the screw brackets 156 are arranged opposite to the engagement structure 154 and extend in a second direction opposite to the first direction. In an embodiment, the engagement structure 154 includes a protrusion 166, while each of the screw brackets 156 includes a hole 168 through which a screw extends inside the associated boss 144 to couple the screw brackets 156 with the screw mounts 140.

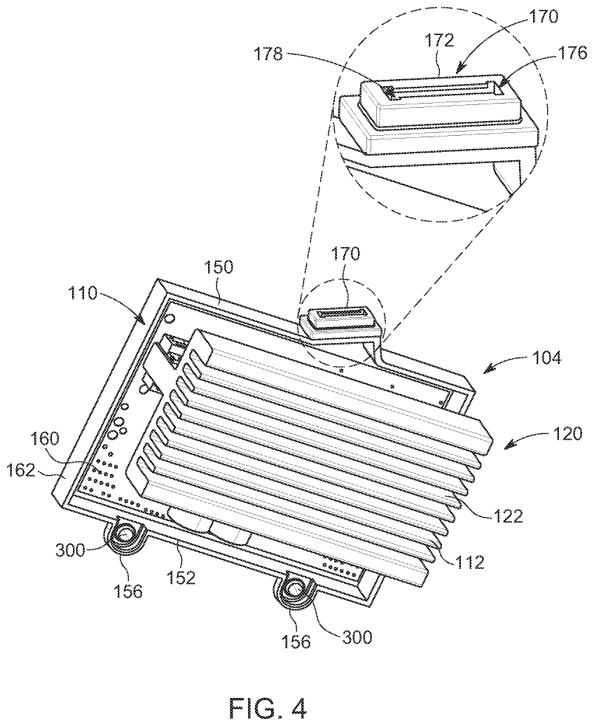

To facilitate the coupling of the engagement structure 154 of the casing 110 with the bracket 130 of the frame 102, the controller assembly 104 includes at least one grommet 170 having a first surface 172 (shown in FIG. 2 and FIG. 4) and a second surface 174 (shown in FIG. 4) arranged opposite to the first surface 172. As shown, the first surface 172 defines a retention structure 176 having a receptacle 178 to receive at least a portion of the bracket 130 of the frame 102. To facilitate a secure attachment of the bracket 130 and the grommet 170, the receptacle 178 includes a shape complimentary of the bracket 130. Accordingly, in the illustrated embodiment, the receptacle 178 includes a horizontally oriented I shape. The grommet 170 is engaged with the bracket 130 by inserting, for example, press fitting, at least a portion of the bracket 130 inside the receptacle 178.

Further, as shown in FIG. 5, the second surface 174 of the grommet 170 defines a cavity 180 having a shape complimentary to the engagement structure 154 i.e., the protrusion 166 of the casing 110. As with the bracket 130, the engagement structure 154 is inserted, for example, press fitted, inside the cavity 180 of the grommet 170. In an embodiment, an interference fit may be achieved between the engagement structure 154 and the grommet 170. Further, due to the coupling of the engagement structure 154 of the casing 110 with bracket 130 of the frame via the grommet 170 restricts the motion of the casing 110, and hence the controller assembly 104, in two mutually perpendicular axes, for example along an X-axis and a Y-axis, while the coupling of the screw mounts 140 with the screw brackets 156 via the screws 300 restricts the movement of the case along a Z-axis. In this manner, the casing 110, and hence the controller assembly 104, is securely mounted to the power unit 100 using the grommet 170 and the screws 300, and the motion of the casing 110, and hence the controller assembly 104, along all three axes is restricted/prevented. In an embodiment, the grommet 170 may be made of a rubber or any similar flexible material to facilitate an absorption of the vibration generated during the operation of the power equipment 200. In some embodiments, the grommet 170 may be made of nylon. Although the grommet 170 made of rubber or nylon is contemplated, it may be appreciated that the grommet 170 may be made of any other suitable material, such as, but not limited to, metal, plastic, alloy, etc., known in the art.

A method for mounting the controller assembly 104 to the power unit 100 of the power equipment 200 is now described. The method includes mounting or assembling the grommet 170 to the casing 110. For so doing, the engagement structure 154 i.e., the protrusion 166 of the casing 110 is inserted inside the cavity 180 of the grommet 170. Thereafter, the casing 110 is mounted to the frame 102 by inserting the bracket 130 of the frame 102 inside the receptacle 178 of the grommet 170. In a non-limiting embodiment, the bracket 130 is press fitted inside the receptacle 178. Subsequently, the screws brackets 156 of the casing 110 are aligned with the screw mounts 140 of the frame, and are coupled/engaged/attached with each other by inserting the fasteners (i.e., screws 300) through the bosses 144 and the holes 168 of the screw brackets 156. Accordingly, a motion of the casing 110 relative to the frame in direction substantially parallel to Z axis is restricted or prevented. this manner, the controller assembly 104 is securely mounted to the power unit 100.

The foregoing description of embodiments and examples has been presented for purposes of illustration and description. It is not intended to be exhaustive or to limit the invention to the forms described. Numerous modifications are possible in light of the above teachings. Some of those modifications have been discussed and others will be understood by those skilled in the art. The embodiments were chosen and described in order to best illustrate certain principles and various embodiments as are suited to the particular use contemplated. The scope of the invention is, of course, not limited to the examples or embodiments set forth herein, but can be employed in any number of applications and equivalent devices by those of ordinary skill in the art. Rather it is hereby intended the scope of the invention be defined by the claims appended hereto.

What is claimed is:

1. A controller assembly for a power unit, the controller assembly comprising:
a controller;
a casing for supporting the controller and adapted to be mounted to a frame of the power unit, the casing including
at least one engagement structure arranged at a first end of the casing and configured to be coupled to the frame, and
a plurality of screw brackets arranged at a second end disposed opposite to the first end and configured to facilitate a coupling of the casing with the frame via a plurality of fasteners; and
at least one grommet adapted to be removably engaged with the at least one engagement structure and the frame to enable the mounting of the casing to the frame.

2. The controller assembly of claim 1, wherein the at least one engagement structure includes a protrusion and the at least one grommet includes a cavity to receive the protrusion to enable the engagement of the at least one grommet with the casing.

3. The controller assembly of claim 1, wherein the at least one grommet includes a receptacle to receive a portion of the frame to facilitate the engagement of the at least one grommet with the frame.

4. The controller assembly of claim 3, wherein the receptacle includes a horizontally oriented I shape.

5. The controller assembly of claim 1, wherein the at least one grommet is arranged between the casing and the frame in an assembly of the at least one grommet with the casing and the frame.

6. The controller assembly of claim 1, wherein
the engagement of the engagement structure with the frame by the at least one grommet restricts a movement of the casing along a first axis and a second axis extending perpendicularly to the first axis, and
the coupling of the plurality of screw brackets with the frame by the plurality of screws restricts a movement of the casing along a third axis extending perpendicularly to both the first axis and the second axis.

7. The controller assembly of claim 1, wherein the at least one grommet is made of rubber to absorb vibrations.

8. A power unit for a power equipment, comprising:
a frame having at least one bracket; and
a controller assembly removably mounted to the frame and including
a controller,
a casing for supporting the controller and mounted to the frame, the casing includes
at least one engagement structure arranged at a first end of the casing and configured to be coupled to the at least one bracket, and
a plurality of screw brackets arranged at a second end disposed opposite to the first end and configured to facilitate a coupling of the casing with the frame via a plurality of fasteners, and
at least one grommet removably coupling the at least one engagement structure of the casing with the at least bracket of the frame.

9. The power unit of claim 8, wherein the at least one engagement structure includes a protrusion and the at least one grommet includes a cavity to receive the protrusion.

10. The power unit of claim 8, wherein the at least one grommet includes a receptacle to receive the at least one bracket.

11. The power unit of claim 10, wherein the receptacle includes a horizontally oriented I shape and the bracket includes a protrusion having a horizontally oriented I shape.

12. The power unit of claim 8, wherein the at least one grommet is arranged between the casing and the frame in an assembly of the at least one grommet with the casing and the frame.

13. The power unit of claim 8, wherein
the coupling of the engagement structure with the at least one bracket by the at least one grommet restricts a movement of the casing along a first axis and a second axis extending perpendicularly to the first axis, and
the coupling of the plurality of screw brackets with the frame by the plurality of screws restricts a movement of the casing along a third axis extending perpendicularly to both the first axis and the second axis.

14. The power unit of claim 8, wherein the at least one grommet is made of rubber to absorb vibrations.

15. The power unit of claim 8, wherein the frame includes a plurality of screw mounts coupled to the screw brackets via the plurality of screws.

16. The power unit of claim 15, wherein each of the plurality of screw mounts includes a boss and each of the plurality of screw brackets includes a hole, and the plurality of screws extends through the associated bosses and the holes in an assembly of the casing with the frame.

17. A controller assembly for a power unit, the controller assembly comprising:
a controller;
a casing for supporting the controller and adapted to be mounted to a frame of the power unit, the casing including
at least one engagement structure arranged at a first end of the casing and configured to be coupled to the frame, the at least one engagement structure includes a protrusion, and
a plurality of screw brackets arranged at a second end disposed opposite to the first end and configured to facilitate a coupling of the casing with the frame via a plurality of fasteners; and
at least one grommet made of rubber and configured to couple the casing and the frame, wherein the at least one grommet defines
a cavity to receive the protrusion of the at least one engagement structure to couple the casing with the at least one grommet, and
a receptacle to receive the at least one bracket of the frame to enable a coupling of the at least one grommet with the frame.

18. The controller assembly of claim 17, wherein the at least one grommet is arranged between the casing and the frame in an assembly of the grommet with the casing and the frame.

19. The controller assembly of claim 18, wherein
the coupling of the casing with the frame by the at least one grommet restricts a movement of the casing along a first axis and a second axis extending perpendicularly to the first axis, and
the coupling of the casing with the frame by the plurality of screws restricts a movement of the casing along a third axis extending perpendicularly to both the first axis and the second axis.

20. The controller assembly of claim 17, wherein the receptacle includes a horizontally oriented I shape and the bracket includes a protrusion having a horizontally oriented I shape.
